(19) United States
(12) Patent Application Publication
(10) Pub. No.: US 2025/0172609 A1
(43) Pub. Date: May 29, 2025

(54) PROBE TESTING APPARATUS, PROBE TESTING SYSTEM AND PROBE CARD

(71) Applicant: Renesas Electronics Corporation, Tokyo (JP)

(72) Inventors: Hisayoshi HANAI, Tokyo (JP); Masaaki TANIMURA, Tokyo (JP); Koji SUZUKI, Tokyo (JP)

(21) Appl. No.: 18/910,332

(22) Filed: Oct. 9, 2024

(30) Foreign Application Priority Data
Nov. 27, 2023 (JP) 2023-199554

(51) Int. Cl. G01R 31/28

(52) U.S. Cl. CPC G01R 31/2875; G01R 31/2877

(57) ABSTRACT

A probe testing apparatus includes a wafer stage, a temperature sensor, a temperature adjustment mechanism, and a controller. The wafer stage includes a wafer mounting surface on which a semiconductor wafer is mounted. The temperature sensor includes a temperature observation point exposed on the wafer mounting surface, and directly measures a temperature of a rear surface of the semiconductor wafer mounted on the wafer mounting surface. The temperature adjustment mechanism adjusts a temperature of the wafer stage by heating or cooling the wafer stage. The controller controls the temperature adjustment mechanism in such a manner that a measured temperature by the temperature sensor becomes a target temperature.

### CROSS-REFERENCE TO RELATED APPLICATIONS

The disclosure of Japanese Patent Application No. 2023-199554 filed on Nov. 27, 2023 including the specification, drawings and abstract is incorporated herein by reference in its entirety.

### BACKGROUND

The present invention relates to a probe testing apparatus, a probe testing system, and a probe card, and relates to, for example, a temperature measurement technique during a probe testing.

There are disclosed techniques listed below.
[Non-Patent Document 1] Japanese Unexamined Patent Application Publication No. 2003-142537

Patent Document 1 discloses a semiconductor testing probe apparatus that can apply equal pressure to all probes when probing electrode pads over a large area. Specifically, on the stage of the probe apparatus, a spacer having the same thickness as the wafer is installed around the wafer mounting region. As a result, the probe structure is pressed while facing both the wafer and the spacer, thereby preventing the probe structure from being inclined with respect to the surface of the wafer.

### SUMMARY

In recent years, as semiconductor devices such as System on Chip (SoC), in other words, semiconductor chips, have become larger and more highly integrated, the number of signal, power and other terminals per semiconductor chip can be several thousand or more, for example. Therefore, when a probe testing is performed for such a semiconductor chip as a device under test, the number of probes connected to these terminals is also enormous. As a result, when the testing temperature of the device under test during the probe testing is determined, it can be difficult to set the actual temperature of the device under test to a target temperature with high accuracy.

Specifically, in order to determine the testing temperature of the device under test, a probe testing apparatus controls the temperature of a wafer stage on which a semiconductor wafer including the device under test is mounted, for example, based on a temperature sensor incorporated in the wafer stage. However, if the device under test is set to a high temperature through the wafer stage, for example, heat dissipation through the probes can occur in the device under test at the time when a large number of probes are in contact with the device under test.

Meanwhile, heat generation can occur in the device under test during the probe testing due to the increased power consumption associated with larger size and higher integration. Here, the wafer stage usually has a higher thermal resistance than the device under test. Therefore, the temperature change in the device under test due to the heat dissipation and heat generation described above is hardly conducted to the wafer stage. As a result, there can be a deviation between the set temperature of the wafer stage and the actual temperature of the device under test.

Other problems and novel features will become apparent from the description of the present specification and the accompanying drawings.

A probe testing apparatus according to an embodiment includes a wafer stage, a temperature sensor, a temperature adjustment mechanism, and a controller. The wafer stage includes a wafer mounting surface on which a semiconductor wafer is mounted. The temperature sensor includes a temperature observation point exposed on the wafer mounting surface, and directly measures a temperature of a rear surface of the semiconductor wafer mounted on the wafer mounting surface. The temperature adjustment mechanism adjusts a temperature of the wafer stage by heating or cooling the wafer stage. The controller controls the temperature adjustment mechanism in such a manner that a measured temperature by the temperature sensor becomes a target temperature.

By using a probe testing apparatus according to an embodiment, it is possible to set an actual temperature of a device under test with high accuracy.

### BRIEF DESCRIPTION OF THE DRAWINGS

FIG. 1A is a schematic diagram illustrating a premised configuration example and an example of a problem in a probe testing system according to a first embodiment.

FIG. 1B is a schematic diagram illustrating an arrangement configuration example of a temperature sensor embedded in a stage surface layer in FIG. 1A.

FIG. 2A is a schematic diagram illustrating a configuration example of a main part of the probe testing system according to the first embodiment.

FIG. 2B is a schematic diagram illustrating an arrangement configuration example of a probe and a temperature sensor in FIG. 2A.

FIG. 3 is a block diagram illustrating a configuration example of a controller in a prober in FIG. 2A.

FIG. 4A is a schematic diagram illustrating a configuration example of a main part of a probe testing system according to a second embodiment.

FIG. 4B is a schematic diagram illustrating an arrangement configuration example of a probe card and a temperature sensor in FIG. 4A.

FIG. 5 is a schematic diagram illustrating an example of a method of predicting an actual temperature of a device under test in FIGS. 4A and 4B.

FIG. 6 is a block diagram illustrating a configuration example of a controller in a prober in FIG. 4A.

FIG. 7A is a schematic diagram illustrating a configuration example of a main part of a probe testing system according to a third embodiment.

FIG. 7B is a schematic diagram illustrating a configuration example of a temperature adjustment mechanism in FIG. 7A.

FIG. 8 is a schematic diagram illustrating an example of a method of flattening a temperature of an entire semiconductor wafer in FIGS. 7A and 7B.

FIG. 9 is a schematic diagram illustrating an example of a result of flattening the temperature of the entire semiconductor wafer using the method illustrated in FIG. 8.

FIG. 10 is a block diagram illustrating a configuration example of a controller in a prober in FIG. 7A.

FIG. 11 is a flowchart illustrating an example of processing details of the controller illustrated in FIG. 10.

FIG. 12 is a schematic diagram illustrating an example of processing details of a temperature calculation unit in FIG. 10.

FIG. 13 is a block diagram illustrating a configuration example in which the controller illustrated in FIG. 10 is modified in a probe testing system according to a fourth embodiment.

FIG. 14A is a flowchart illustrating an example of processing details of the controller illustrated in FIG. 13.

FIG. 14B is a flowchart illustrating an example of processing details of the controller illustrated in FIG. 13.

FIG. 15A is a schematic diagram illustrating a configuration example of a main part of a probe testing system according to a fifth embodiment.

FIG. 15B is a schematic diagram illustrating an arrangement configuration example of a temperature sensor in FIG. 15A.

FIG. 16 is a block diagram illustrating a configuration example of a controller in a prober in FIG. 15A.

FIG. 17 is a schematic diagram illustrating an example of a premised problem and a countermeasure against the problem in a probe testing system according to a sixth embodiment.

FIG. 18 is a block diagram illustrating a configuration example of a temperature controller included in a controller in a prober in the probe testing system according to the sixth embodiment.

FIG. 19 is a flowchart illustrating an example of processing details of the controller in the prober in the probe testing system according to the sixth embodiment.

FIG. 20 is a supplementary diagram for explaining a part of the processing details illustrated in FIG. 19.

### DETAILED DESCRIPTION

In the following embodiments, when necessary for convenience, the description will be made by dividing them into a plurality of sections or embodiments, but unless otherwise specified, they are not unrelated to each other, and one is related to part or all of the others as a modification, detail, additional explanation, or the like. In addition, in the following embodiments, when referring to the number of elements and the like (including the number of pieces, numerical values, amounts, ranges, and the like), unless otherwise specified or clearly limited to a specific number in principle, the number is not limited to the specific number, and the number may be equal to or greater than the specific number, or may be equal to or less than the specific number.

Furthermore, in the following embodiments, it is needless to say that the constituent elements (including element steps and the like) are not necessarily essential unless otherwise specified or considered to be obviously essential in principle. Similarly, in the following embodiments, when referring to the shape, positional relationship, and the like of the constituent elements and the like, it is assumed to include those substantially approximating or similar to the shape and the like, unless otherwise specified or unless it is clear that this is not the case in principle. The same applies to the above numerical values and ranges.

Hereinafter, embodiments will be described in detail with reference to the accompanying drawings. Note that, in all the drawings for describing the embodiments, members having the same functions are denoted by the same reference signs, and the repetitive description thereof will be omitted. In addition, in the following embodiments, the description of the same or similar parts is generally not repeated unless particularly required.

### First Embodiment

### <Configuration and Problem of Probe Testing System (Premise)>

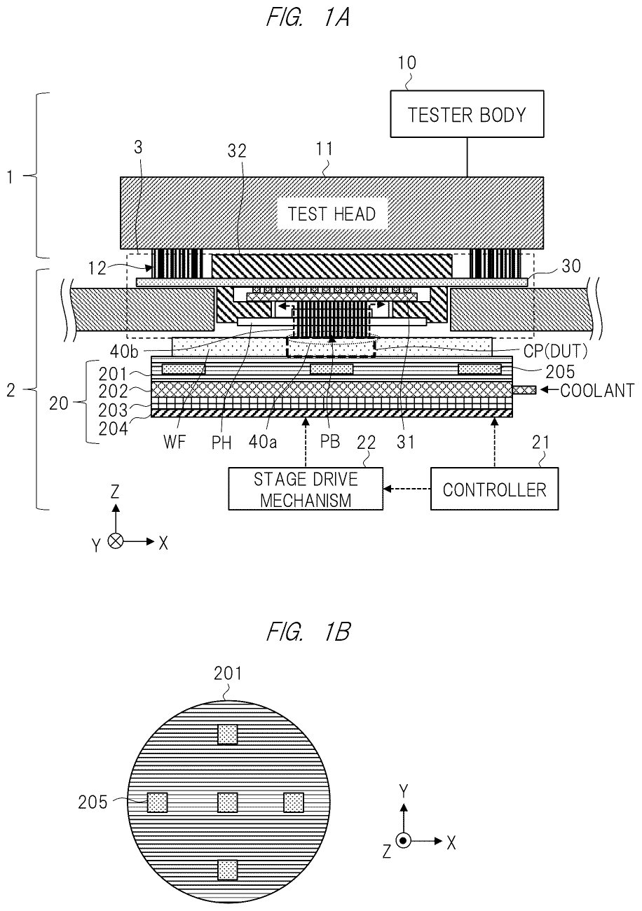

FIG. 1A is a schematic diagram illustrating a premised configuration example and an example of a problem in a probe testing system according to a first embodiment. FIG. 1B is a schematic diagram illustrating an arrangement configuration example of a temperature sensor 205 embedded in a stage surface layer 201 in FIG. 1A. The probe testing system illustrated in FIG. 1A includes a tester 1, a prober (probe testing apparatus) 2, and a probe card 3.

The tester 1 includes a tester body 10 and a test head 11. The test head 11 includes a driver that outputs a signal to the outside, a receiver that receives a signal from the outside, a power supply unit that supplies a power supply voltage or a power supply current to the outside and can measure the power supply current or the power supply voltage, and the like. The tester body 10 controls an output signal from the driver, power from the power supply unit, and the like based on a predetermined testing program and the like, and evaluates an input signal to the receiver, a measurement value in the power supply unit, and the like.

The prober 2 includes a wafer stage 20 called a wafer chuck or the like, a controller 21, and a stage drive mechanism 22. The wafer stage 20 mounts and adsorbs a semiconductor wafer WF on its wafer mounting surface. On the semiconductor wafer WF, a plurality of semiconductor chips CP, which is also a device under test DUT, are formed. The wafer stage 20 includes, for example, an insulating layer 204, a heater layer 203, a cooling layer 202, and a stage surface layer 201, which are sequentially stacked toward the wafer mounting surface.

A plurality of temperature sensors 205 is embedded in the stage surface layer 201. For example, as illustrated in FIG. 1B, the temperature sensors 205 are arranged in a substantially uniformly dispersed manner within the region of the stage surface layer 201. The heater layer 203 heats the wafer stage 20, specifically, the stage surface layer 201. On the other hand, the cooling layer 202 cools the wafer stage 20, specifically, the stage surface layer 201.

As a result, the semiconductor wafer WF is heated and cooled through the stage surface layer 201, and the testing temperature of the device under test DUT is adjusted. In the specification, the heater layer 203 and the cooling layer 202, which adjust the temperature of the wafer stage 20, which ultimately means the device under test DUT, by heating or cooling the wafer stage 20 in this manner, are collectively referred to as temperature adjustment mechanisms (202, 203).

The controller 21 includes, for example, a processor, a memory, and the like, and controls the entire prober 2 based on a control program stored in the memory. As one of the control, the controller 21 controls the temperature adjustment mechanisms (202, 203) in such a manner that a measured temperature by the temperature sensors 205 becomes a target temperature. Note that the controller 21 may be implemented not only by software processing by the processor, but also by hardware processing by, for example, an application specific integrated circuit (ASIC), a field programmable gate array (FPGA), or the like, or by a combination of software processing and hardware processing.

The probe card 3 is connected to the test head 11 via a test interface 12. The probe card 3 is configured to be detachable from each of the test head 11 and the prober 2. The probe card 3 includes a main board 30, a conversion board 31, a reinforcing plate 32, and a probe head PH to which a plurality of probes PB is attached. The reinforcing plate 32 connects the main board 30 and the conversion board 31, and fixes the connected state. The probe head PH is mounted on the conversion board 31.

The main board 30 includes a plurality of wires connecting between the test interface 12 and the conversion board 31, and transmits a signal or power through the wires. The conversion board 31 includes a plurality of wires connecting between the main board 30 and the probes PB, and transmits a signal or power through the wires.

The stage drive mechanism 22 moves the wafer stage 20 in an X-axis direction, a Y-axis direction, and a Z-axis direction in response to an instruction from the controller 21. In the specification, the plane direction of the semiconductor wafer WF or the plane direction of the wafer mounting surface of the wafer stage 20 is defined as the X-axis direction and the Y-axis direction perpendicular to the X-axis direction, and the direction perpendicular to the X-axis direction and the Y-axis direction is defined as the Z-axis direction. When the device under test DUT is tested, the stage drive mechanism 22 moves the wafer stage 20 in the X-axis direction and the Y-axis direction, and then moves the wafer stage 20 in the Z-axis direction in such a manner that the probes PB come into contact with the terminal of the device under test DUT.

In such a probe testing system, when the semiconductor chip CP, which is the device under test DUT is, for example, an SoC or the like, the number of terminals per one semiconductor chip CP can be several thousand or more. Accordingly, the number of probes PB that come into contact with the terminals also increases, and the overall volume of the probes PB also increases. Here, the probes PB are made of a conductor material having a relatively small thermal resistance. For this reason, when the probes PB having a large volume are brought into contact with the device under test DUT that has been set to a high temperature, for example, heat dissipation 40b can occur from the device under test DUT to the tester 1 installed in a normal temperature environment.

In addition, in the device under test DUT, heat generation 40a also occurs due to power consumption during a probe testing. Therefore, the actual temperature of the device under test DUT during the probe testing is a temperature at which the heat generation 40a and the heat dissipation 40b are in equilibrium, which can be a temperature that is difficult to predict. On the other hand, the stage surface layer 201 usually has higher thermal resistance than the semiconductor wafer WF. Therefore, the heat of the device under test DUT is easily conducted to the entire semiconductor wafer WF, but is hardly conducted to the stage surface layer 201.

As a result, the measured temperature by the temperature sensors 205 embedded in the stage surface layer 201 does not necessarily indicate the actual temperature of the device under test DUT, and can be a temperature that deviates to some extent from the actual temperature of the device under test DUT. In this case, even if the temperature adjustment mechanisms (202, 203) are controlled based on the measured temperature by the temperature sensors 205, the actual temperature of the device under test DUT cannot be set to a desired testing temperature. As described above, in the premised probe testing system, it is difficult to set the actual temperature of the semiconductor chip CP, which is the device under test DUT, with high accuracy. Therefore, it is advantageous to use a method of the embodiment described later.

### <Configuration of Probe Testing System (Embodiment)>

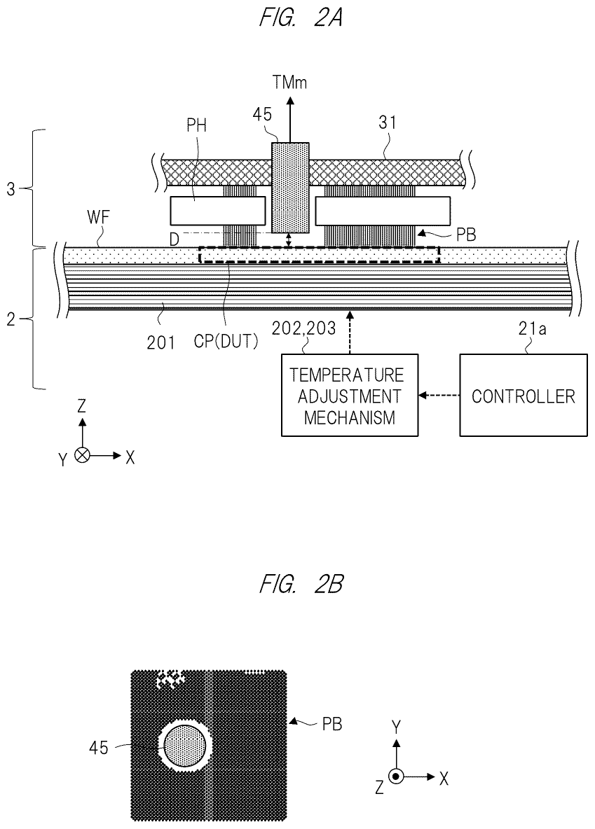

FIG. 2A is a schematic diagram illustrating a configuration example of a main part of the probe testing system according to the first embodiment. FIG. 2B is a schematic diagram illustrating an arrangement configuration example of a probe PB and a temperature sensor 45 in FIG. 2A; FIG. 2A illustrates a configuration example of a part of the probe card 3 and a part of the prober (probe testing apparatus) 2 among the constituent elements described in FIG. 1A.

Unlike the case of FIG. 1A, the temperature sensor 45, which is a non-contact type, is attached to the probe card 3 illustrated in FIG. 2A. The temperature sensor 45 is attached to the probe card 3, specifically, the conversion board 31, the main board 30 (not illustrated), or the like in such a manner that the temperature observation point is arranged at a predetermined distance D from the surface of the semiconductor wafer WF, in this case, the device under test DUT during a probe testing. As a result, the temperature sensor 45 measures the temperature of the device under test DUT in a non-contact manner during the probe testing, and outputs data on a measured temperature TMm.

Specifically, as illustrated in FIGS. 2A and 2B, the temperature observation point of the temperature sensor 45 is arranged above the inner region of the device under test DUT and at a position where the probes PB are not arranged. The term “above” means a direction on the Z-axis. With such an arrangement, the temperature sensor 45 can measure the actual temperature of the device under test DUT actually tested in the semiconductor wafer WF.

Specific examples of the configuration of the non-contact type temperature sensor 45 include a fiber type radiation thermometer and the like. The radiation thermometer condenses infrared rays emitted from a measurement object, in this case, the device under test DUT, at the temperature observation point, and takes the infrared rays into an optical fiber. Then, the radiation thermometer detects the infrared rays transmitted through the optical fiber with an infrared sensor and converts the infrared rays into a temperature. When such the temperature sensor 45 is used, the probe head PH is provided with, for example, a through-hole through which an optical fiber is passed, as illustrated in FIG. 2A.

### <Details of Controller>

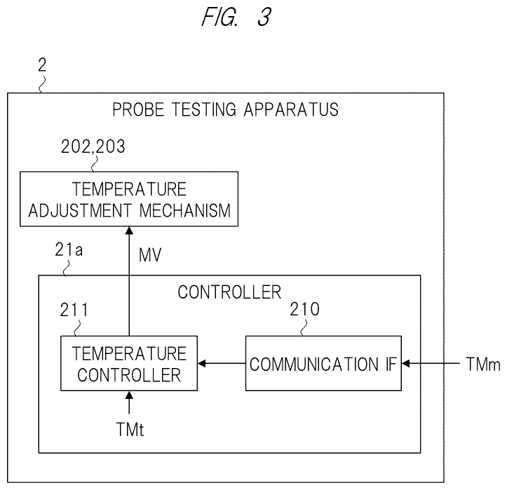

FIG. 3 is a block diagram illustrating a configuration example of a controller 21a in the prober 2 in FIG. 2A. The controller 21a illustrated in FIG. 3 includes a communication interface (IF) 210 and a temperature controller 211. The communication interface (IF) 210 acquires the measured temperature TMm by the temperature sensor 45, more specifically, data on the measured temperature TMm. At this time, the communication interface (IF) 210 acquires the measured temperature TMm by direct communication with the temperature sensor 45 or indirect communication via the tester 1. In the latter case, the temperature sensor 45 temporarily outputs the data on the measured temperature TMm to the tester body 10.

The temperature controller 211 is implemented by, for example, software processing by a processor. Unlike the case of FIG. 1A, the temperature controller 211 controls the temperature adjustment mechanisms (202, 203) based on the measured temperature TMm acquired via the communication interface (IF) 210. In this example, the temperature controller 211 controls the temperature adjustment mechanisms (202, 203) in such a manner that the measured temperature TMm becomes a target temperature TMt. Specifically, the temperature controller 211 performs proportional integral control (PI control), proportional integral differential control (PID control), or the like based on, for example, an error between the measured temperature TMm and the target temperature TMt to generate a manipulated variable MV for the temperature adjustment mechanisms (202, 203).

### <Main Effects of First Embodiment>

As described above, in the method of the first embodiment, the non-contact type temperature sensor for measuring the actual temperature of the device under test is attached to the probe card, and the temperature of the wafer stage is controlled based on the measured temperature by the temperature sensor. As a result, typically, it is possible to set the actual temperature of the device under test with high precision.

### Second Embodiment

### <Configuration of Probe Testing System (Embodiment)>

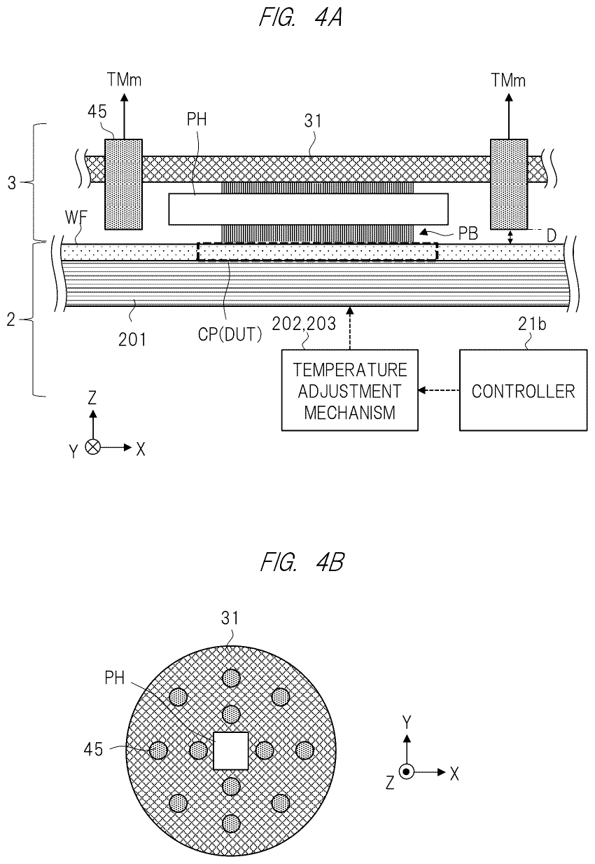

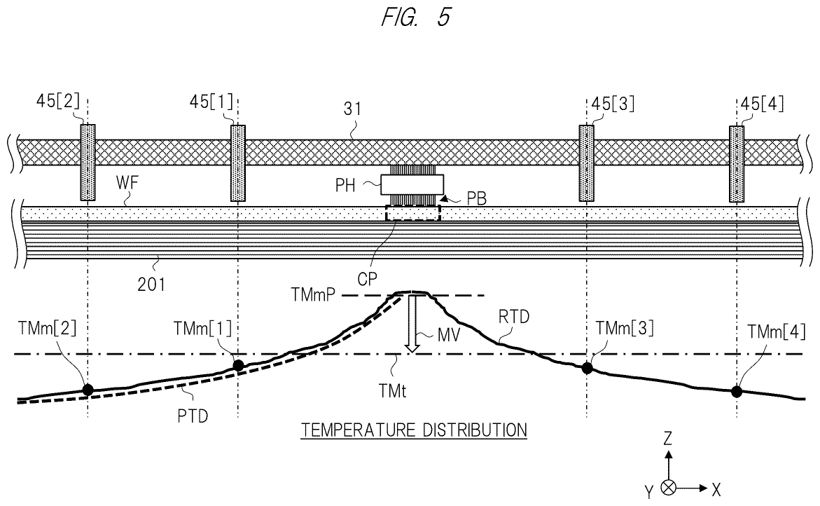

FIG. 4A is a schematic diagram illustrating a configuration example of a main part of a probe testing system according to a second embodiment. FIG. 4B is a schematic diagram illustrating an arrangement configuration example of a probe card 3 and a temperature sensor 45 in FIG. 4A. FIG. 4A illustrates a configuration example of a part of the probe card 3 and a part of the prober (probe testing apparatus) 2 among the constituent elements described in FIG. 1A, as in the case of FIG. 2A.

The temperature sensor 45, which is a non-contact type, is attached to the probe card 3 illustrated in FIG. 4A, as in the case of FIG. 2A. However, in this example, unlike the case of FIG. 2A, the temperature observation point of the temperature sensor 45 is arranged above not the inner region but the outer region of a device under test DUT during a probe testing. Furthermore, in this example, the probe card 3 includes a plurality of temperature sensors 45. For example, as illustrated in FIG. 4B, the temperature observation points of the temperature sensors 45 are arranged in a substantially uniformly dispersed manner within the region of the probe card 3, specifically, the conversion board 31.

Here, in the configuration example illustrated in FIGS. 2A and 2B described above, the temperature sensor 45 is arranged in the inner region of the device under test DUT and the region where the probes PB are not arranged. In this case, there can be an arrangement restriction in the terminal of the semiconductor chip CP with which the probes PB come into contact, or there can be a manufacturing restriction in the probe card 3. In addition, if the number of probes PB itself is reduced, the test specification may be affected. On the other hand, when the configuration example illustrated in FIGS. 4A and 4B is used, such restrictions and the like do not occur. Therefore, a probe testing can be performed on various semiconductor chips CP.

However, in the configuration example illustrated in FIGS. 4A and 4B, unlike the case of FIGS. 2A and 2B, the temperature sensors 45 are not disposed above the device under test DUT, and thus the temperature of the device under test DUT cannot be directly measured. Therefore, in this case, the actual temperature of the device under test DUT is predicted by, for example, a method as illustrated in FIG. 5. FIG. 5 is a schematic diagram illustrating an example of a method of predicting an actual temperature of the device under test DUT in FIGS. 4A and 4B.

FIG. 5 illustrates an example of a relationship between measured temperatures TMm[1] to TMm[4] by four temperature sensors 45[1] to 45[4] attached to the conversion board 31 and temperature distribution RTD formed on a semiconductor wafer WF. For example, if the device under test DUT generates a large amount of heat during a probe testing, the temperature distribution RTD of the semiconductor wafer WF is formed, with the position of the device under test DUT as the apex, as illustrated in FIG. 5. The measured temperatures TMm[1] to TMm[4] by the four temperature sensors 45[1] to 45[4] are temperatures based on the temperature distribution RTD.

On the other hand, the relative positional relationship between, for example, the attachment position of the temperature sensor 45[2], the attachment position of the temperature sensor 45[1], and the position of the device under test DUT is always fixed. Therefore, as illustrated in FIG. 5, the temperature of the device under test DUT can be predicted as a predicted temperature TMmP based on the measured temperatures TMm[2] and TMm[1] by the temperature sensors 45[2] and 45[1] and predetermined predicted temperature distribution PTD. The predicted temperature distribution PTD is created by, for example, performing an experiment in advance or a temperature simulation, and is held in a memory in the form of a formula, a table, or the like.

For example, a controller 21b is only required to calculate the predicted temperature TMmP in this manner to control the temperature adjustment mechanisms (202, 203) in such a manner that the predicted temperature TMmP becomes a target temperature TMt. Note that, in this example, two temperature sensors 45[1] and 45[2] positioned in one direction with respect to the position of the device under test DUT are used to perform temperature prediction. On the other hand, the position and number of the temperature sensors 45 to be used can be appropriately changed. However, it is desirable to perform temperature prediction based on the temperature gradient, and it is preferable to use at least two or more temperature sensors 45.

### <Details of Controller>

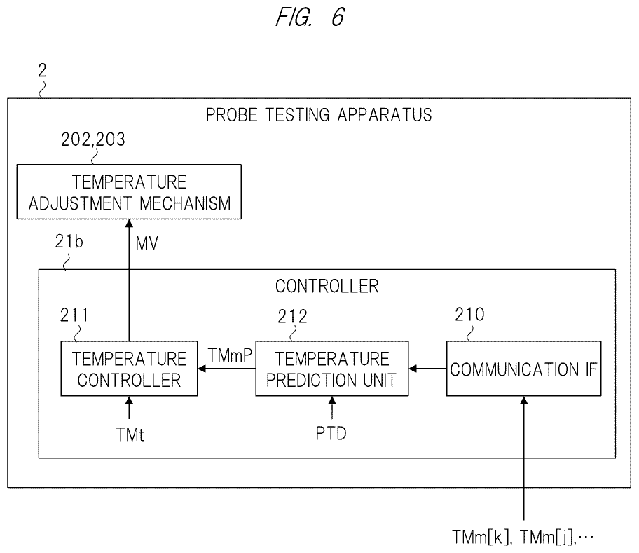

FIG. 6 is a block diagram illustrating a configuration example of the controller 21b in the prober 2 in FIG. 4A. The controller 21b illustrated in FIG. 6 includes a temperature prediction unit 212 in addition to the communication interface (IF) 210 and the temperature controller 211 illustrated in FIG. 3. The temperature prediction unit 212 is implemented by, for example, software processing by a processor. The communication interface (IF) 210 acquires the measured temperatures TMm[k], TMm[j], . . . , and so on by the predetermined temperature sensors 45.

The controller 21b controls the temperature adjustment mechanisms (202, 203) using the temperature prediction unit 212 and the temperature controller 211 based on the measured temperatures TMm[k], TMm[j], . . . , and so on acquired via the communication interface (IF) 210. Specifically, as described in FIG. 5, the temperature prediction unit 212 predicts the temperature of the device under test DUT as the predicted temperature TMmP based on the measured temperatures TMm[k], TMm[j], . . . , and so on and the predicted temperature distribution PTD. The temperature controller 211 generates a manipulated variable MV as in the case of FIG. 3, for example, and controls the temperature adjustment mechanisms (202, 203) in such a manner that the predicted temperature TMmP becomes the target temperature TMt.

### <Main Effects of Second Embodiment>

As described above, by using the method of the second embodiment, effects substantially similar to the various effects described in the first embodiment can be obtained, and typically, the actual temperature of the device under test can be set with high accuracy. Furthermore, unlike the method of the first embodiment, there is no restriction in the terminal of the semiconductor chip CP or the probes PB, it is possible to perform a probe testing on various semiconductor chips CP.

### Third Embodiment

### <Configuration of Probe Testing System (Embodiment)>

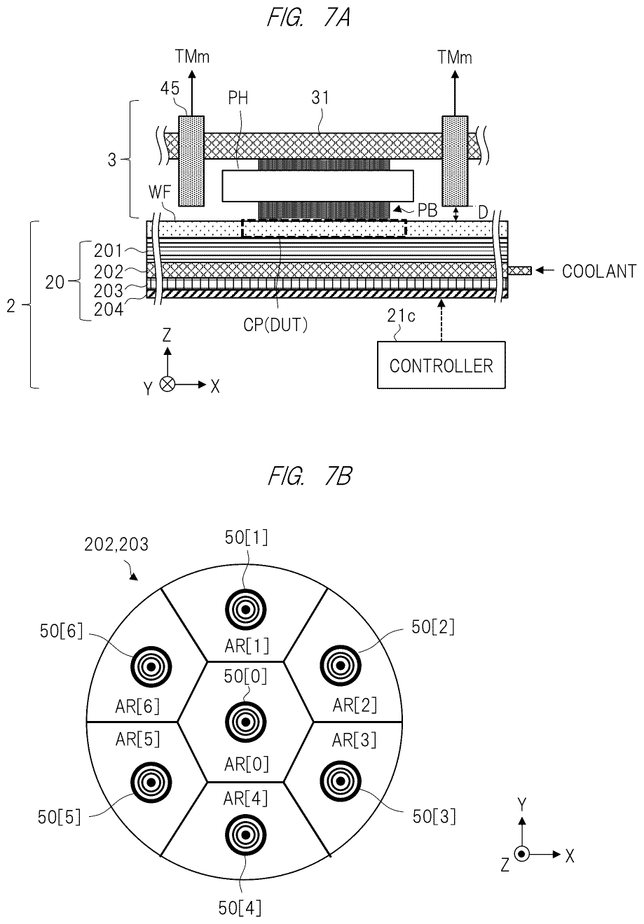

FIG. 7A is a schematic diagram illustrating a configuration example of a main part of a probe testing system according to a third embodiment. FIG. 7B is a schematic diagram illustrating a configuration example of the temperature adjustment mechanisms (202, 203) in FIG. 7A. FIG. 7A illustrates a configuration example of a part of the probe card 3 and a part of the prober (probe testing apparatus) 2 among the constituent elements described in FIG. 1A, as in the case of FIG. 4A. Here, the configuration of the probe card 3 is similar to the case of FIGS. 4A and 4B described in the second embodiment. On the other hand, the prober 2 is different from the case of FIG. 4A in the configuration of the temperature adjustment mechanisms (202, 203).

That is, in FIG. 4A, the temperature adjustment mechanisms (202, 203) are configured to adjust the entire stage surface layer 201 to a single set temperature. On the other hand, the temperature adjustment mechanisms (202, 203) in FIG. 7A include a plurality of adjustment regions dividing the region of the wafer mounting surface, and is configured to adjust the temperatures of the adjustment regions individually.

Specifically, as illustrated in FIG. 7B, the temperature adjustment mechanisms (202, 203) include a plurality of, seven in this example, adjustment regions AR[0] to AR[6], and include divided temperature adjustment mechanisms 50[0] to 50[6] in the seven adjustment regions AR[0] to AR[6], respectively. The divided temperature adjustment mechanisms 50[0] to 50[6] adjust the temperatures of the adjustment regions AR[0] to AR[6] by heating or cooling, respectively. In the specification, the adjustment regions AR[0] to AR[6] are collectively referred to as adjustment regions AR. In addition, the divided temperature adjustment mechanisms 50[0] to 50[6] are collectively referred to as divided temperature adjustment mechanisms 50.

Here, when there is one adjustment region AR, that is, in the case of FIG. 4A, mainly two problems can arise. As a first problem, as illustrated in the temperature distribution RTD in FIG. 5, the temperature gradient can be large, and as a result, the accuracy of predicting the actual temperature of the device under test DUT can decrease. As a second problem, for example, as a result of lowering the temperature of the entire stage surface layer 201 in order to lower the actual temperature of the device under test DUT, the temperature can be excessively lowered in the region of the semiconductor wafer WF excluding the region of the device under test DUT. In this case, for example, when the device under test DUT is moved, the settling time required for the device under test DUT after the movement to reach the target temperature can increase.

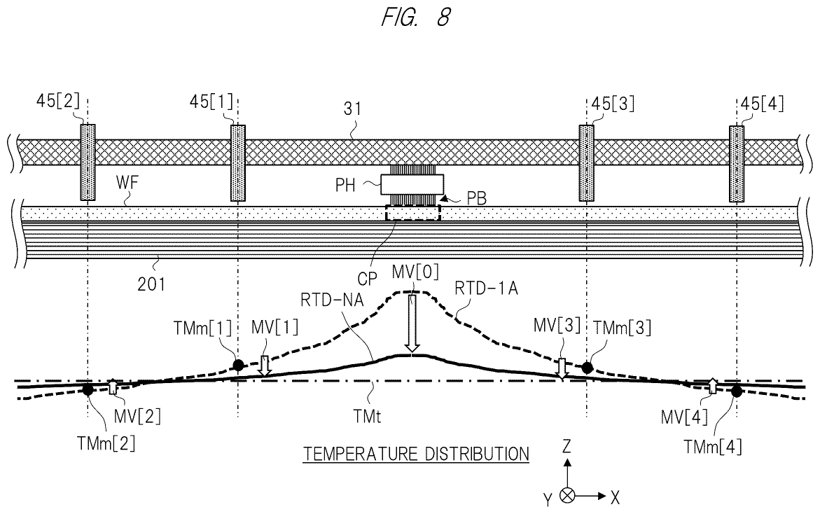

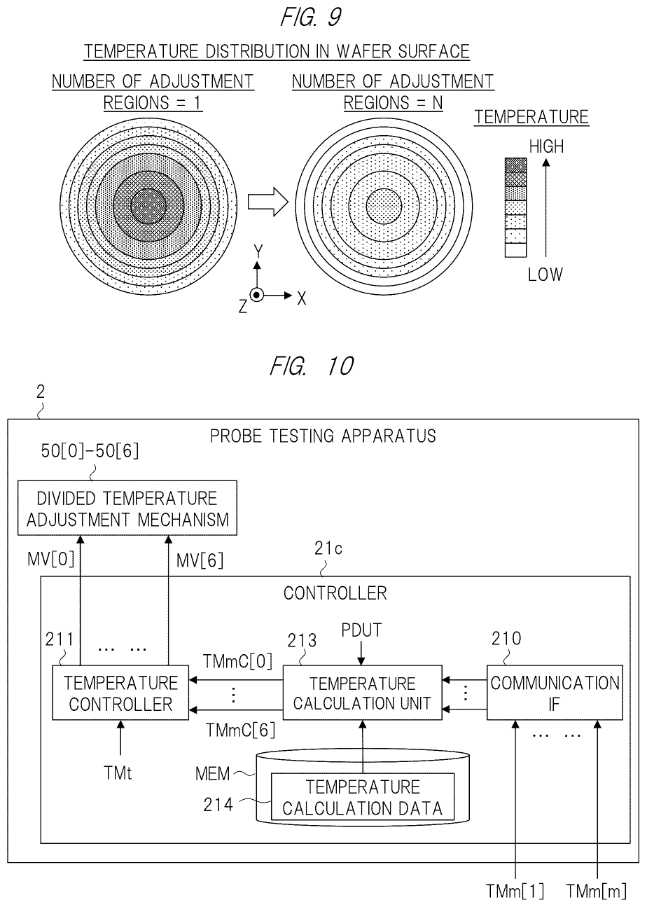

Therefore, in the third embodiment, the temperature of the entire semiconductor wafer WF is flattened by using the divided temperature adjustment mechanisms 50 as illustrated in FIG. 7B. FIG. 8 is a schematic diagram illustrating an example of a method of flattening the temperature of the entire semiconductor wafer WF in FIGS. 7A and 7B. FIG. 9 is a schematic diagram illustrating an example of a result of flattening the temperature of the entire semiconductor wafer WF using the method illustrated in FIG. 8.

In FIG. 8, as in the case of FIG. 5, the four temperature sensors 45[1] to 45[4] attached to the conversion board 31 first obtain the measured temperatures TMm[1] to TMm[4] based on temperature distribution RTD-1A similar to FIG. 5. In such a state, unlike the case of FIG. 5, independent manipulated variables MV[0] to MV[4] are added to the respective adjustment regions AR in FIG. 8.

As a result, as illustrated in FIGS. 8 and 9, when the number of adjustment regions is plural (N), flattened temperature distribution RTD-NA is obtained as compared to the temperature distribution RTD-1A when the number of adjustment regions AR is one. By flattening the temperature distribution semiconductor wafer WF in this manner, the temperature gradient becomes small, and as a result, the actual temperature of the device under test DUT can be set to the target temperature TMt with high accuracy. Furthermore, when the device under test DUT is moved, the initial temperature of the device under test DUT after the movement can also be close to the target temperature TMt, which can shorten the settling time after movement.

### <Details of Controller>

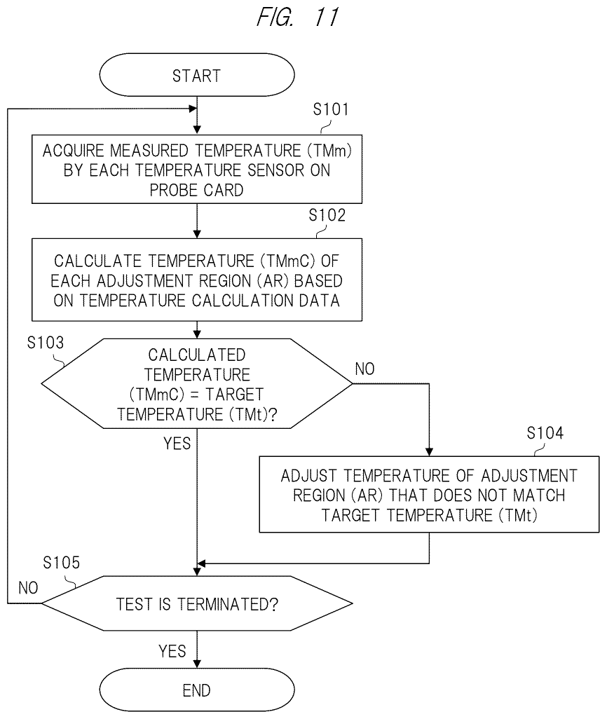

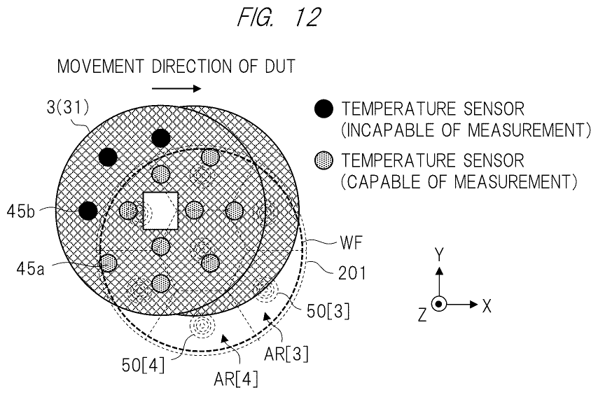

FIG. 10 is a block diagram illustrating a configuration example of a controller 21c in the prober 2 in FIG. 7A. FIG. 11 is a flowchart illustrating an example of processing details of the controller 21c illustrated in FIG. 10. FIG. 12 is a schematic diagram illustrating an example of processing details of a temperature calculation unit 213 in FIG. 10.

The controller 21c illustrated in FIG. 10 includes the temperature calculation unit 213 instead of the temperature prediction unit 212 illustrated in FIG. 6. The temperature calculation unit 213 is implemented by, for example, software processing by a processor. The communication interface (IF) 210 acquires the measured temperatures TMm[1] to TMm[m] by all the temperature sensors 45. The controller 21c controls the divided temperature adjustment mechanisms 50[0] to 50[6] using the temperature calculation unit 213 and the temperature controller 211 based on the measured temperature TMm[1] to TMm[m] acquired via the communication interface (IF) 210.

Here, details of the temperature calculation unit 213 are described with reference to FIG. 12. FIG. 12 illustrates an example of a relative positional relationship among the probe card 3, specifically, the conversion board 31, the stage surface layer 201, the semiconductor wafer WF, and the divided temperature adjustment mechanisms 50. As illustrated in FIG. 12, the relative positional relationship between the semiconductor wafer WF and the adjustment regions AR[0] to AR[6] illustrated in FIG. 7B is always fixed. Therefore, if the temperature distribution of the entire semiconductor wafer WF is determined, the temperatures of the respective adjustment regions AR[0] to AR[6] in the semiconductor wafer WF are also determined. Based on these, the manipulated variables for the divided temperature adjustment mechanisms 50[0] to 50[6] can be individually controlled.

On the other hand, the relative positional relationship between the probe card 3, which ultimately means the temperature sensors 45, and the semiconductor wafer WF changes according to the position of the device under test DUT. Accordingly, depending on the position of the device under test DUT, there are a temperature sensor 45a capable of measuring the temperature of the semiconductor wafer WF and a temperature sensor 45b incapable of measuring the temperature. Therefore, for each position of the device under test DUT, it is necessary to obtain the temperature distribution of the entire semiconductor wafer WF, which ultimately means the temperature of each of the adjustment regions AR[0] to AR[6], based on the measured temperature TMm acquired by the temperature sensor 45a capable of measuring the temperature.

Therefore, as illustrated in FIG. 10, the temperature calculation unit 213 calculates the temperatures of the respective adjustment regions AR[0] to AR[6] in the semiconductor wafer WF as calculated temperatures TMmC[0] to TMmC[6] based on position information PDUT on the device under test DUT and the measured temperatures TMm[1] to TMm[m] by the temperature sensors 45. As a result, for example, the unmeasured temperatures of the adjustment regions AR[3] and AR[4] are also obtained in the case of FIG. 12.

In addition, in order to perform such temperature calculation, the controller 21c holds temperature calculation data 214 in a memory MEM in advance. The temperature calculation data 214 is constituted by, for example, mathematical data or conversion table data for obtaining the calculated temperatures TMmC[0] to TMmC[6] of the respective adjustment regions AR[0] to AR[7] from the measured temperatures TMm by the temperature sensors 45a capable of measurement for each position of the device under test DUT. The temperature calculation data 214 can be created by, for example, performing an experiment in advance or performing a temperature simulation.

The temperature controller 211 controls the temperatures of the adjustment regions AR[0] to AR[6] individually in such a manner that the calculated temperatures TMmC[0] to TMmC[6] of the respective adjustment regions AR[0] to AR[6] from the temperature calculation unit 213 each become the target temperature TMt. Specifically, the temperature controller 211 includes, for example, seven PI controllers or the like to generate the manipulated variables MV[0] to MV[6] for the respective divided temperature adjustment mechanisms 50[0] to 50[6], and control the divided temperature adjustment mechanisms 50[0] to 50[6] individually.

FIG. 11 illustrates schematic processing details of the controller 21c. The flowchart is implemented by, for example, a processor executing a control program stored in a memory. In FIG. 11, the controller 21c, specifically, the communication interface (IF) 210 first acquires the measured temperature TMm by each temperature sensor 45 on the probe card 3 (step S101).

Then, the controller 21c, specifically, the temperature calculation unit 213 calculates the temperature of each adjustment region AR as a calculated temperature TMmC based on the temperature calculation data 214 provided in advance (step S102). Next, the controller 21c, specifically, the temperature controller 211 compares the calculated temperature TMmC with the target temperature TMt (step S103). Here, the controller 21c proceeds to step S105 when the calculated temperature TMmC matches the target temperature TMt (step S103: YES), and proceeds to step S105 through step S104 when the calculated temperature TMmC does not match the target temperature TMt (step S103: NO).

In step S104, the temperature controller 211 adjusts the temperature of the adjustment region AR that does not match the target temperature TMt using the divided temperature adjustment mechanism 50 of the corresponding region so as to match the target temperature TMt. In addition, in step S105, the controller 21c returns to step S101 and performs similar processing unless the probe testing is terminated. That is, the controller 21c repeatedly performs the processing of steps S101 to S104 at a predetermined control cycle.

### <Main Effects of Third Embodiment>

As described above, by using the method of the third embodiment, effects substantially similar to the various effects described in the second embodiment can be obtained, and typically, the actual temperature of the device under test can be set with high accuracy. That is, in the method of the third embodiment, the actual temperature of the device under test can be set with high accuracy by flattening the temperature distribution of the semiconductor wafer. Furthermore, by flattening the temperature distribution of the semiconductor wafer, it is possible to shorten the settling time of the temperature required when the device under test is moved.

### Fourth Embodiment

### <Details of Controller>

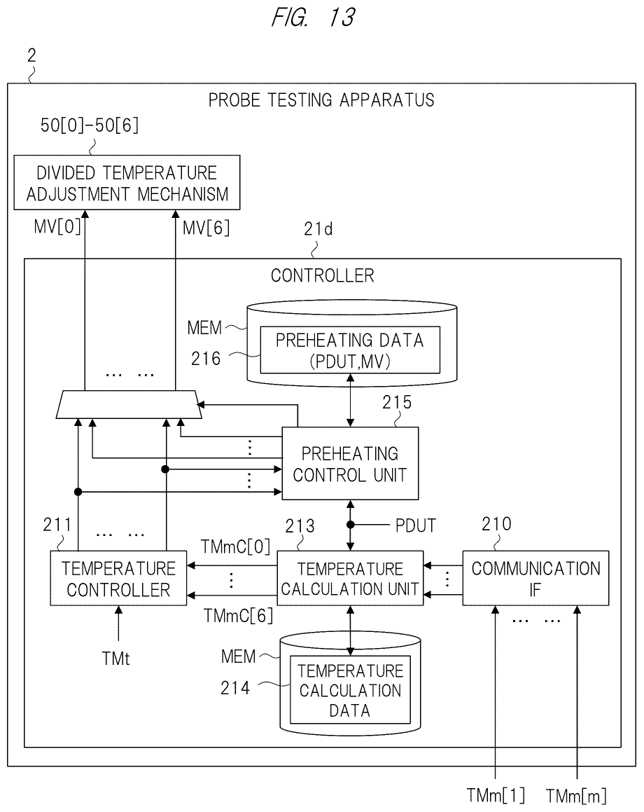

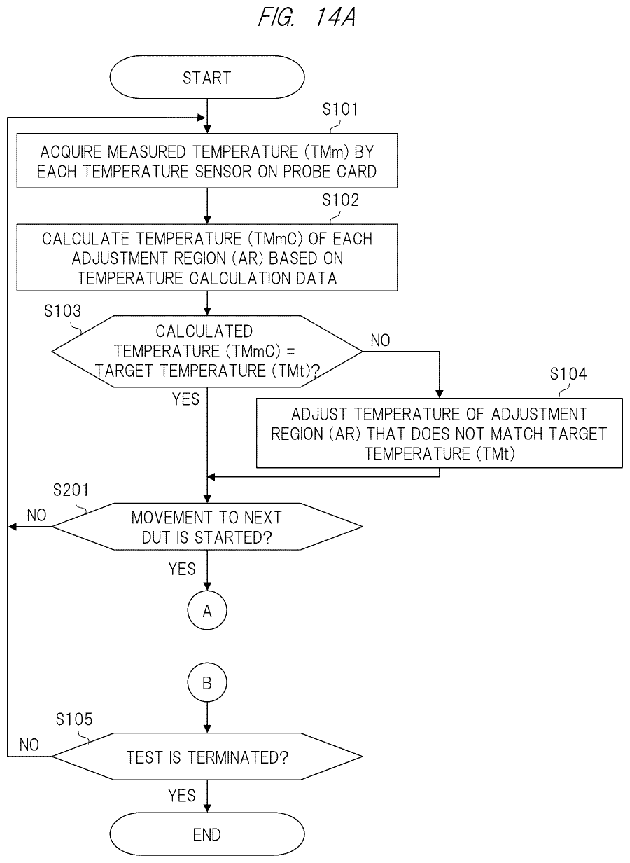

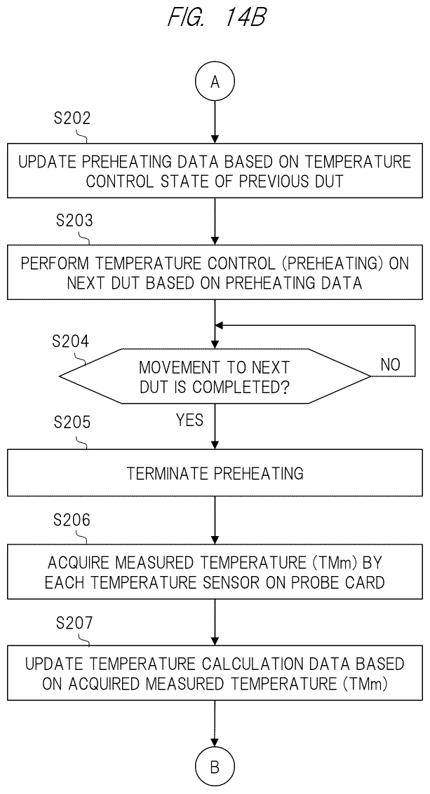

FIG. 13 is a block diagram illustrating a configuration example in which the controller illustrated in FIG. 10 is modified in a probe testing system according to a fourth embodiment. FIGS. 14A and 14B are flowcharts illustrating an example of processing details of a controller 21d illustrated in FIG. 13. The overall configuration of the probe testing system according to the fourth embodiment is similar to the case of FIGS. 7A and 7B. The controller 21d illustrated in FIG. 13 further includes a preheating control unit 215 and preheating data 216 as compared to the configuration example illustrated in FIG. 10. The preheating control unit 215 is implemented by, for example, software processing by a processor.

Here, for example, if the method of the third embodiment described above is used, the semiconductor wafer WF is separated from the probe card 3 by the movement of the wafer stage 20 in the Z-axis direction when the movement of the device under test DUT is started. For this reason, the temperature sensors 45 cannot measure the temperature of the semiconductor wafer WF, and a control loop for controlling the divided temperature adjustment mechanisms 50 is not normally formed.

Therefore, the preheating control unit 215 receives the manipulated variables MV[0] to MV[6] for the respective adjustment regions AR[0] to AR[6] from the temperature controller 211 during a probe testing period. Then, the preheating control unit 215 holds the received manipulated variables MV[0] to MV[6] in the memory MEM as the preheating data 216 for each position of the device under test DUT, that is, for each position information PDUT. The preheating control unit 215 outputs the manipulated variables MV[0] to MV[6] based on the preheating data 216 to the divided temperature adjustment mechanisms 50[0] to 50[6] in a period from the start to the completion of the movement of the device under test DUT to control the temperatures of the adjustment regions AR[0] to AR[6].

At this time, more desirably, the preheating control unit 215 controls the temperatures of the adjustment regions AR[0] to AR[6] individually in advance based on the preheating data 216 corresponding to the position of the device under test DUT after the movement. That is, in a chronological explanation, the preheating data 216 is created or updated, for example, when a probe testing is performed on a certain semiconductor wafer WF. Then, the created or updated preheating data 216 is applied when a probe testing is performed on the next semiconductor wafer WF.

Here, the manipulated variables MV[0] to MV[6] for the divided temperature adjustment mechanisms 50[0] to 50[6] are different values from each other as illustrated in FIG. 8, for example, and also change according to the position of the device under test DUT. Therefore, it is desirable to control the divided temperature adjustment mechanism 50[0] to 50[6] in advance before the movement is actually completed, based on the preheating data 216 corresponding to the position of the device under test DUT after the movement. As a result, it is possible to further shorten the settling time of the temperature of the device under test DUT after the movement.

FIGS. 14A and 14B illustrate schematic processing details of the controller 21d. The flowchart is implemented by, for example, a processor executing a control program stored in a memory. In the flowcharts illustrated in FIGS. 14A and 14B, the processing of steps S201 to S207 is inserted between step S103 or S104 and step S105 in the flowchart illustrated in FIG. 11.

In step S201, the controller 21d repeatedly performs the processing of steps S101 to S104, that is, the processing by the communication interface (IF) 210, the temperature calculation unit 213, and the temperature controller 211 unless the movement to the next device under test DUT is started. On the other hand, when the movement to the next device under test DUT is started (step S201: YES), the controller 21d, specifically, the preheating control unit 215 associates the manipulated variables MV generated, for example, in steps S103 and S104 with the position information PDUT on the device under test DUT, and updates the preheating data 216 (step S202).

Subsequently, the preheating control unit 215 outputs the manipulated variables MV to the divided temperature adjustment mechanisms 50 instead of the temperature controller 211 based on the preheating data 216 for the next device under test DUT after the movement to perform the temperature control of each adjustment region AR, that is, preheating. Then, the preheating control unit 215 waits for completion of the movement to the next device under test DUT (step S204). Then, when the movement to the next device under test DUT is completed (step S204: YES), the preheating control unit 215 terminates the preheating, and switches in such a manner that the manipulated variables MV are output from the temperature controller 211 to the divided temperature adjustment mechanisms 50 (step S205).

Next, the controller 21d, specifically, the communication interface (IF) 210 acquires the measured temperature TMm by each temperature sensor 45 on the probe card 3 (step S206). As a result, the controller 21d may update the temperature calculation data 214 based on the acquired measured temperature TMm (step S207). That is, in step S206, by the movement of the device under test DUT, the temperature of the unmeasured region, that is, the region of the semiconductor wafer WF that has not been overlap with the probe card 3 in FIG. 12 can be measured. By using this measurement result, the temperature calculation data 214 can be updated or corrected to be more accurate.

### <Main Effects of Fourth Embodiment>

As described above, by using the method of the fourth embodiment, effects substantially similar to the various effects described in the third embodiment can be obtained, and typically, the actual temperature of the device under test can be set with high accuracy. Furthermore, by performing preheating, it is possible to further shorten the settling time of the temperature of the device under test after the movement as compared to the method of the third embodiment.

### Fifth Embodiment

### <Configuration of Probe Testing System (Embodiment)>

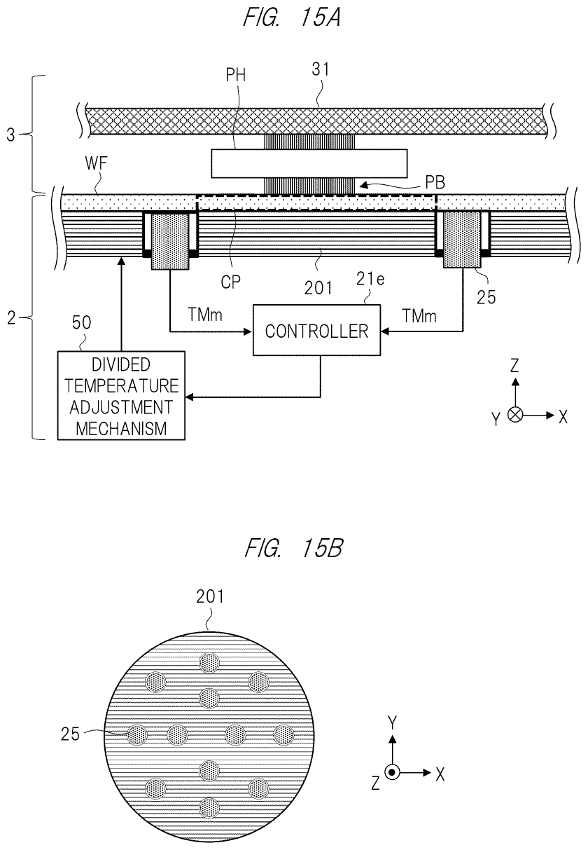

FIG. 15A is a schematic diagram illustrating a configuration example of a main part of a probe testing system according to a fifth embodiment. FIG. 15B is a schematic diagram illustrating an arrangement configuration example of a temperature sensor 25 in FIG. 15A. FIG. 15A illustrates a configuration example of a part of the probe card 3 and a part of the prober (probe testing apparatus) 2 among the constituent elements described in FIG. 1A. In FIG. 15A, unlike the cases of the first to fourth embodiments, the probe card 3 does not include the temperature sensor 45 and is configured as usual.

Instead, the prober 2 includes the temperature sensor 25 different from the temperature sensor 205 embedded in the stage surface layer 201 as described in FIGS. 1A and 1B. The temperature sensor 25 includes a temperature observation point exposed on the wafer mounting surface of the stage surface layer 201, and directly measures the temperature of the rear surface of the semiconductor wafer WF mounted on the wafer mounting surface without interposing a metal member or the like of the stage surface layer 201. As a result, the actual temperature of the semiconductor wafer WF can be measured with high accuracy.

The temperature sensor 25 may be a non-contact type or a contact type. However, as illustrated in FIG. 15A, it is desirable to use the contact type temperature sensor 25. The contact type temperature sensor 25 measures the temperature of the semiconductor wafer WE by the temperature observation point coming into contact with the rear surface of the semiconductor wafer WF. By using type, the expansion of the temperature measurement range or the further improvement of the temperature measurement accuracy can be easily achieved as compared to the case of using a non-contact type. Examples of the contact type temperature sensor 25 include an RTD sensor using a resistance value of a resistance temperature detector such as platinum, a thermistor using the resistance temperature characteristics of a semiconductor, and a thermocouple using the Seebeck effect.

In addition, in this example, a plurality of temperature sensors 25 is provided as illustrated in n FIG. 15B. The temperature observation points of the temperature sensors 25 are arranged in a substantially uniformly dispersed manner within the region of the wafer mounting surface in the stage surface layer 201. The prober 2 illustrated in FIG. 15A further includes divided temperature adjustment mechanisms 50 as illustrated in FIG. 7B in this example.

When such a configuration example is used, unlike the cases of the first to fourth embodiments, it is not necessary to attach the temperature sensor 45 to the probe card 3, which can be required for each product, and the cost can be reduced. Furthermore, for example, a method similar to that of the third embodiment or the fourth embodiment can be achieved without performing temperature calculation as described in FIG. 12 or the like, or by performing simple temperature calculation.

That is, unlike the cases of FIG. 12 and the like, the relative positional relationship between the temperature sensors 25 and the semiconductor wafer WF, which ultimately means the adjustment regions AR, is always fixed. Therefore, the temperature distribution of the semiconductor wafer WF is directly obtained from the measured temperatures TMm by the temperature sensors 25, and the temperature of each of the adjustment regions AR is obtained based on the temperature distribution.

Here, more desirably, the temperature observation points of the temperature sensors 25 are arranged so as to correspond to the respective adjustment regions AR. That is, it is preferable that the temperature sensors 25[0] to 25[6] are arranged in the respective adjustment regions AR[0] to AR[6] in FIG. 7B in addition to the divided temperature adjustment mechanisms 50[0] to 50[6]. In this case, since the temperature of each of the adjustment regions AR can be directly obtained, temperature control becomes easy, and an error or the like associated with temperature calculation does not occur.

### <Details of Controller>

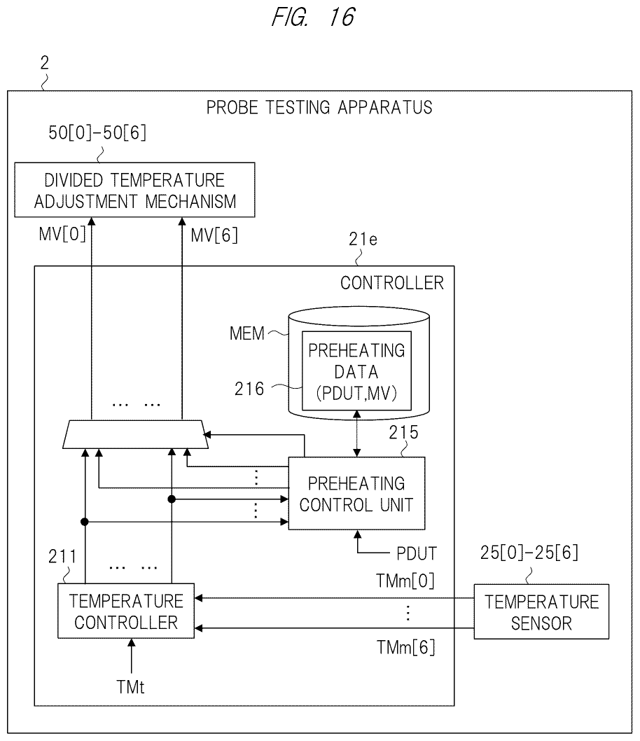

FIG. 16 is a block diagram illustrating a configuration example of a controller 21e in the prober 2 in FIG. 15A. Here, it is assumed that a method similar to that of the fourth embodiment is achieved using the configuration example illustrated in FIG. 15A. In addition, as described above, it is assumed that the temperature sensors 25 are arranged in the respective adjustment regions AR. Unlike the configuration example illustrated in FIG. 13, the controller 21e illustrated in FIG. 16 is not provided with the communication interface (IF) 210, the temperature calculation unit 213, and the temperature calculation data 214.

The temperature controller 211 receives the measured temperatures TMm[0] to TMm[6] from the temperature sensors 25[0] to 25[6]. Then, the temperature controller 211 controls the temperatures of the adjustment regions AR[0] to AR[6] individually in such a manner that received measured temperatures TMm[0] to TMm[6] each become the target temperature TMt. Specifically, the temperature controller 211 generates the manipulated variables MV[0] to MV[6] for the respective divided temperature adjustment mechanisms 50[0] to 50[6] in a similar manner to the case of FIG. 10, for example, and controls the divided temperature adjustment mechanisms 50[0] to 50[6] individually. As described above, since the communication interface (IF) 210 is unnecessary, it is possible to shorten a delay in acquiring the measured temperatures TMm, which ultimately means a delay in controlling the temperature.

In addition, regarding the preheating control unit 215, in this case, unlike the case of FIG. 13, a control loop from the temperature sensors 25[0] to 25[6] to the divided temperature adjustment mechanisms 50[0] to 50[6] is always formed, regardless of the movement of the device under test DUT. Therefore, the preheating control unit 215 is not necessarily required. However, it is advantageous to provide the preheating control unit 215 from the viewpoint of performing preheating according to the position of the device under test DUT after the movement.

Note that, in this case, an example of achieving a method similar to that of the third embodiment or the fourth embodiment has been described using the configuration example illustrated in FIG. 15A. In addition to this, in some cases, it is also possible to achieve a method similar to that of the second embodiment, that is, the method as illustrated in FIG. 5 by using the configuration example illustrated in FIG. 15A. In this case, the controller 21 is only required to predict the temperature of the device under test DUT based on the measured temperatures TMm by the temperature sensors 25 and the position information PDUT on the device under test DUT.

### <Main Effects of Fifth Embodiment>

As described above, by using the method of the fifth embodiment, effects substantially similar to the various effects described in the third embodiment or the fourth embodiment can be obtained, and typically, the actual temperature of the device under test can be set with high accuracy. In addition, it is possible to reduce the cost involved in manufacturing the probe card, and further facilitate the temperature control.

### Sixth Embodiment

### <Premised Problems and Countermeasures>

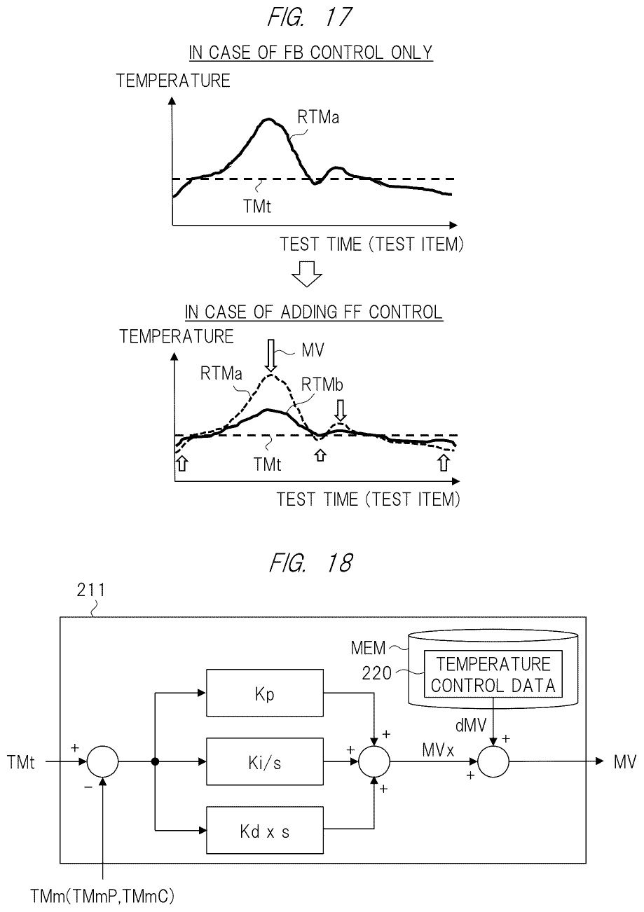

FIG. 17 is a schematic diagram illustrating an example of a premised problem and a countermeasure against the problem in a probe testing system according to a sixth embodiment. The amount of self-generated heat in the device under test DUT varies depending on the test being performed. In addition, for example, when temperature feedback control (FB control) is performed, it is difficult to follow a temperature change due to a difference in the amount of self-generated heat at a high speed in a normal control band. Therefore, as illustrated in the upper part of FIG. 17, an actual temperature RTMa of the device under test DUT can change significantly to some extent in time series during a testing period.

Therefore, in the sixth embodiment, feedforward control (FF control) is performed by generating a manipulated variable MV that reflects time-series changes in the actual temperature RTMa in advance. As a result, as illustrated in the lower part of FIG. 17, the device under test DUT is set to an actual temperature RTMb, which has suppressed temperature changes. Note that the method of the sixth embodiment can be applied in combination with any of the methods of the first to fifth embodiments described above.

### <Details of Controller>

FIG. 18 is a block diagram illustrating a configuration example of a temperature controller 211 included in a controller in a prober in the probe testing system according to the sixth embodiment. The temperature controller 211 illustrated in FIG. 18 includes a PID controller in this example. The PID controller performs PID control using a proportional coefficient Kp, an integral coefficient Ki, and a derivative coefficient Kd based on an error between the measured temperature TMm, the predicted temperature TMmP, or the calculated temperature TMmC and the target temperature TMt to output a manipulated variable MVx that brings the error close to zero. The temperature changes can also be suppressed to some extent by the PID controller.

Here, the temperature controller 211 further holds the temperature control data 220 in the memory MEM. The temperature control data 220 is data generated in advance based on the time-series temperature changes in the device under test DUT within a probe testing period, that is, the actual temperature RTMa illustrated in FIG. 17 so as to offset the temperature changes. The temperature controller 211 performs feedforward control on the temperature adjustment mechanisms (202, 203) or the divided temperature adjustment mechanisms 50 based on the temperature control data 220 during the probe testing period. Specifically, for example, the temperature controller 211 generates the final manipulated variable MV by adding a time-series correction manipulated variable dMV based on the temperature control data 220 to the manipulated variable MVx from the PID controller.

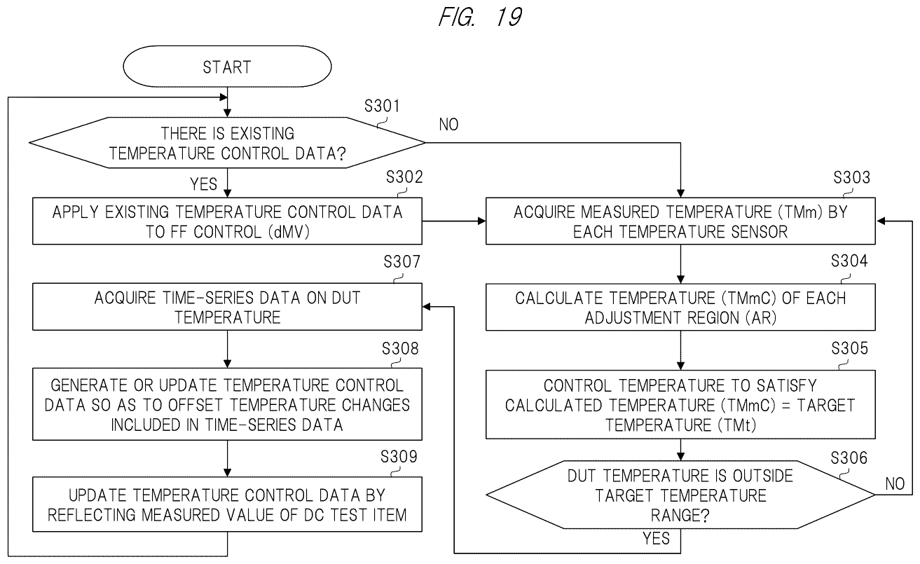

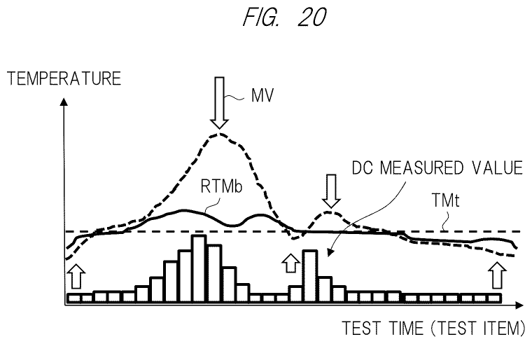

FIG. 19 is a flowchart illustrating an example of processing details of the controller in the prober in the probe testing system according to the sixth embodiment. FIG. 20 is a supplementary diagram for explaining a part of the processing details illustrated in FIG. 19. Here, a case in which the configuration example as illustrated in FIG. 18 is applied to the method of the third embodiment, that is, the temperature controller 211 illustrated in FIG. 10 is described as an example.

In FIG. 19, the controller 21 first determines whether there is existing temperature control data 220 (step S301). When there is existing temperature control data 220 (step S301: YES), the controller 21 applies the existing temperature control data 220 and proceeds to step S303. In this case, in the subsequent processing, the temperature controller 211 performs FF control using the correction manipulated variable dMV as illustrated in FIG. 18. On the other hand, when there is no existing temperature control data 220 (step S301: NO), the controller 21 directly proceeds to step S303.

In step S303, the controller 21 acquires the measured temperature TMm by each temperature sensor 45. Subsequently, the controller 21 calculates the temperature of each adjustment region AR based on the acquired measured temperature TMm (step S304). Then, the controller 21 performs temperature control in such a manner that the calculated temperature TMmC becomes the target temperature TMt (step S305). Here, the controller 21 determines whether the temperature of the device under test DUT, for example, the measured temperature T′Mm by any of the temperature sensors 45 is outside a predetermined target temperature range (step S306).

When the temperature of the device under test DUT is within the target temperature range (step S306: NO), the controller 21 returns to step S303 and repeats the same processing. On the other hand, when the temperature of the device under test DUT is outside the target temperature range (step S306: YES), the controller 21 acquires time-series data on the temperature of the device under test DUT (step S307). Subsequently, the controller 21 newly generates the temperature control data 220 or updates the existing temperature control data 220 so as to offset the temperature changes included in the acquired time-series data (step S308).

Furthermore, the controller 21 may acquire a measured value of a DC test item, for example, a power supply current value from the tester 1, and further update the temperature control data 220 by reflecting the measured value (step S309). That is, as illustrated in FIG. 20, there is usually a correlation between the measured value of the DC test item and the actual temperature RTMb. Therefore, the temperature control data 220 may be updated using the measurement value of the DC test item.

Thereafter, the controller 21 returns to step S301 and repeats similar processing. At this time, the temperature control data 220 created or updated in steps S308 and S309 is applied to, for example, the next device under test DUT or the like as the existing temperature control data. In steps S308 and S309, for example, artificial intelligence (AI) may be caused to learn the relationship between the temperature changes in the device under test DUT and the temperature control data 220 or the measurement value of the DC test item to generate the temperature control data 220 capable of suppressing the temperature changes in the device under test DUT.

### <Main Effects of Sixth Embodiment>

As described above, by using the method of the sixth embodiment, typically, the actual temperature of the device under test can be set with high accuracy. In particular, during a testing period of the device under test, the actual temperature of the device under test can be set with high accuracy while the changes in the actual temperature according to the test item are suppressed.

Although the invention made by the present inventors has been concretely described based on the embodiments, the present invention is not limited to the above embodiments, and it is needless to say that various modifications can be made without departing from the gist of the present invention.

What is claimed is:

1. A probe testing apparatus comprising:
a wafer stage including a wafer mounting surface on which a semiconductor wafer is mounted;
a temperature sensor including a temperature observation point exposed on the wafer mounting surface and configured to directly measure a temperature of a rear surface of the semiconductor wafer mounted on the wafer mounting surface;
a temperature adjustment mechanism configured to adjust a temperature of the wafer stage by heating or cooling the wafer stage; and
a controller configured to control the temperature adjustment mechanism in such a manner that a measured temperature by the temperature sensor becomes a target temperature.

2. The probe testing apparatus according to claim 1,
Wherein the temperature sensor is a contact type temperature sensor configured to measure a temperature of the semiconductor wafer by the temperature observation point coming into contact with the rear surface of the semiconductor wafer.

3. The probe testing apparatus according to claim 2, further comprising:
a plurality of the temperature sensors,
wherein the temperature observation points of the plurality of temperature sensors are arranged in a substantially uniformly dispersed manner within a region of the wafer mounting surface.

4. The probe testing apparatus according to claim 3,
wherein the temperature adjustment mechanism includes a plurality of adjustment regions dividing the region of the wafer mounting surface, and is configured to adjust temperatures of the plurality of adjustment regions individually.

5. The probe testing apparatus according to claim 4,
wherein the temperature observation points of the plurality of temperature sensors are arranged to correspond to the plurality of adjustment regions.

6. The probe testing apparatus according to claim 4,
wherein the controller controls the temperatures of the plurality of adjustment regions individually in such a manner that each of measured temperatures the plurality of temperature sensors becomes the target temperature.

7. The probe testing apparatus according to claim 6,
wherein the controller holds a manipulated variable for the temperatures for each of the plurality of adjustment regions in a memory as preheating data for each position of a device under test formed on the semiconductor wafer, and controls, in a period from a start to a completion of movement of the device under test, the temperatures of the plurality of adjustment regions individually in advance based on the preheating data corresponding to a position of the device under test after the movement.

8. The probe testing apparatus according to claim 1,
wherein the controller further holds temperature control data in a memory, and performs feedforward control on the temperature adjustment mechanism based on the temperature control data in a probe testing period, and
wherein the temperature control data is data generated so as to offset, based on a time-series temperature change in a device under test formed on the semiconductor wafer during the probe testing period, the temperature change.

9. A probe testing system comprising a probe card and a probe testing apparatus,
wherein the probe card includes:
a plurality of probes attached so as to come into contact with a terminal of a device under test formed on a semiconductor wafer during a probe testing; and
a non-contact type temperature sensor attached in such a manner that a temperature observation point is arranged at a predetermined distance from a surface of the semiconductor wafer during the probe testing and configured to measure a temperature of the semiconductor wafer in a non-contact manner, and
wherein the probe testing apparatus includes:
a wafer stage including a wafer mounting surface on which the semiconductor wafer is mounted;
a temperature adjustment mechanism configured to adjust a temperature of the wafer stage by heating or cooling the wafer stage; and
a controller configured to acquire a measured temperature by the temperature sensor attached to the probe card and to control the temperature adjustment mechanism based on the measured temperature.

10. The probe testing system according to claim 9,
wherein the temperature observation point of the temperature sensor is arranged above an inner region of the device under test and at a position where the plurality of probes is not arranged, and
wherein the controller controls the temperature adjustment mechanism in such a manner that the measured temperature becomes a target temperature.

11. The probe testing system according to claim 9, further comprising:
a plurality of the temperature sensors,
wherein temperature observation points of the plurality of temperature sensors are arranged above an outer region of the device under test during the probe testing, and
wherein the controller predicts a temperature of the device under test as a predicted temperature based on the measured temperatures by the plurality of temperature sensors, and controls the temperature adjustment mechanism in such a manner that the predicted temperature becomes a target temperature.

12. The probe testing system according to claim 9, further comprising:
a plurality of the temperature sensors,
wherein the temperature observation points of the plurality of temperature sensors are arranged in a substantially uniformly dispersed manner within a region of the probe card.

13. The probe testing system according to claim 12,
wherein the temperature adjustment mechanism includes a plurality of adjustment regions dividing a region of the wafer mounting surface, and is configured to adjust temperatures of the plurality of adjustment regions individually.

14. The probe testing system according to claim 13,
wherein the controller calculates a temperature of each of the plurality of adjustment regions in the semiconductor wafer based on a position of the device under test and the measured temperatures by the plurality of temperature sensors, and controls the temperatures of the plurality of adjustment regions individually in such a manner that the calculated temperature of each of the plurality of adjustment regions becomes a target temperature.

15. The probe testing system according to claim 14,
wherein the controller holds a manipulated variable for the temperatures for each of the plurality of adjustment regions in a memory as preheating data for each position of the device under test, and controls, in a period from a start to a completion of movement of the device under test, the temperatures of the plurality of adjustment regions individually in advance based on the preheating data corresponding to a position of the device under test after the movement.

16. The probe testing system according to claim 9,
wherein the controller further holds temperature control data in a memory, and performs feedforward control on the temperature adjustment mechanism based on the temperature control data in a probe testing period of the device under test, and
wherein the temperature control data is data generated so as to offset, based on a time-series temperature change in the device under test during the probe testing period, the temperature change.

17. A probe card to be used in a probe testing of a device under test formed on a semiconductor wafer, the probe card comprising:
a plurality of probes attached so as to come into contact with a terminal of the device under test during the probe testing; and
a non-contact type temperature sensor attached in such a manner that a temperature observation point is arranged at a predetermined distance from a surface of the semiconductor wafer during the probe testing and configured to measure a temperature of the semiconductor wafer in a non-contact manner.

18. The probe card according to claim 17,
wherein the temperature observation point of the temperature sensor is arranged, during the probe testing, above an inner region of the device under test and at a position where the plurality of probes is not arranged.

19. The probe card according to claim 17, further comprising:
a plurality of the temperature sensors,
wherein the temperature observation points of the plurality of temperature sensors are arranged above an outer region of the device under test during the probe testing.

20. The probe card according to claim 17, further comprising:
a plurality of the temperature sensors,
wherein the temperature observation points of the plurality of temperature sensors are arranged in a substantially uniformly dispersed manner within a region of the probe card.
